(19) United States
(12) Patent Application Publication
(10) Pub. No.: US 2026/0329438 A1
(43) Pub. Date: Oct. 22, 2026

(54) WRITING DATA TO A MEMORY ARRAY IN A DIFFERENTIAL MEMORY SYSTEM

(71) Applicant: Taiwan Semiconductor Manufacturing Company, Ltd., Hsinchu (TW)

(72) Inventors: Yu-Der CHIH, Hsin-Chu City (TW); Chien-Yin LIU, Hsinchu City (TW); Yi-Cheng HUANG, Hsinchu City (TW); Shang-Hsuan LIU, Zhudong Town (TW); Hsueh-Chih YANG, Hsinchu City (TW)

(21) Appl. No.: 19/262,670

(22) Filed: Jul. 8, 2025

Related U.S. Application Data
(60) Provisional application No. 63/790,391, filed on Apr. 17, 2025.

(51) Int. Cl. G06F 3/06

(52) U.S. Cl. CPC G06F 3/0611; G06F 3/0619; G06F 3/0659; G06F 3/0673

(57) ABSTRACT

Binary values of target data and of complementary data are written into a memory array in a highly parallelized and streamlined manner. As described herein, 1-values of target data and of complementary data may be simultaneously pre-read, and 0-values of target data and of complementary data may also be simultaneously pre-read. The 1-values and the 0-values of the target data and of the complementary data may all be pre-read before writing of the target data and the complementary data is performed. The 1-values and the 0-values of the target data may then be written to a first memory bank of the memory array and verified, and the 1-values and the 0-values of the complementary data may then be written to a second memory bank of the memory array and verified.

### CROSS-REFERENCE TO RELATED APPLICATION

This Patent Application claims priority to U.S. Provisional Patent Application No. 63/790,391, filed on Apr. 17, 2025, and entitled “WRITING DATA TO A MEMORY ARRAY IN A DIFFERENTIAL MEMORY SYSTEM.” The disclosure of the prior Application is considered part of and is incorporated by reference into this Patent Application.

### BACKGROUND

Memory systems are used in a wide variety of electronic device applications, such as computers, cameras, Internet of Things (IoT) devices, mobile phones, data centers, and/or automotive and industrial systems, among other examples. Memory systems are made up of a plurality of memory cells that are typically arranged in an array of a plurality of rows and a plurality of columns. The memory cells of a memory system may be volatile (meaning that data stored by the memory cells is lost when power is removed from the memory system) and/or non-volatile (meaning that data is retained by the memory cells when power is removed from the memory system).

### BRIEF DESCRIPTION OF THE DRAWINGS

Aspects of the present disclosure are best understood from the following detailed description when read with the accompanying figures. It is noted that, in accordance with the standard practice in the industry, various features are not drawn to scale. In fact, the dimensions of the various features may be arbitrarily increased or reduced for clarity of discussion.

FIGS. 1A and 1B are diagrams of an example memory system described herein.

FIG. 2 is a diagram of an example implementation of a write operation for writing differential data to the memory array of the memory system described herein.

FIG. 3 is a diagram of an example implementation of writing differential data to the memory array of the memory system described herein.

FIG. 4 is a diagram of an example implementation of writing differential data to the memory array of the memory system described herein.

FIG. 5 is a diagram of example components of an electronic device described herein.

FIG. 6 is a flowchart of an example process associated with writing data to a memory array in a differential memory system described herein.

FIG. 7 is a flowchart of an example process associated with writing data to a memory array in a differential memory system described herein.

FIG. 8 is a flowchart of an example process associated with writing data to a memory array in a differential memory system described herein.

### DETAILED DESCRIPTION

The following disclosure provides many different embodiments, or examples, for implementing different features of the provided subject matter. Specific examples of components and arrangements are described below to simplify the present disclosure. These are, of course, merely examples and are not intended to be limiting. For example, the formation of a first feature over or on a second feature in the description that follows may include embodiments in which the first and second features are formed in direct contact, and may also include embodiments in which additional features may be formed between the first and second features, such that the first and second features may not be in direct contact. In addition, the present disclosure may repeat reference numerals and/or letters in the various examples. This repetition is for the purpose of simplicity and clarity and does not in itself dictate a relationship between the various embodiments and/or configurations discussed.

A differential memory system is a type of memory system in which 1 (one) bit of data is stored in two memory cells as complementary values. For example, one memory cell may store a first value (e.g., a target binary value, such as a 1-value) for the 1 bit of data, and another memory cell may store a second value (e.g., a complementary binary value, such as a 0-value) for the 1 bit of data. The use of complementary values for data storage may provide for increased robustness and reliability of the data, which may provide for increased data accuracy in applications such as neural networks and artificial intelligence, among other examples. While the differential memory approach may provide for increased data storage robustness, the process for writing complementary values of the data (and verifying those values) may be complex and time consuming, resulting in slower read and write times relative to other types of memory systems.

In some implementations described herein, binary values of target data and of complementary data are written into a memory array in a highly parallelized and streamlined manner, as opposed to a sequential manner, in order to increase write efficiency and to reduce write and read times in a differential memory system. As described herein, 1-values of target data and of complementary data may be simultaneously pre-read, and 0-values of target data and of complementary data may also be simultaneously pre-read. The 1-values and the 0-values of the target data and of the complementary data may all be pre-read before writing of the target data and the complementary data is performed. The 1-values and the 0-values of the target data may then be written to a first memory bank of the memory array and verified, and the 1-values and the 0-values of the complementary data may then be written to a second memory bank of the memory array and verified. In some implementations, the 1-values and the 0-values of the target data and of the complementary data are all written to the memory array in the same write operation.

Batching together the pre-reads for the target data and the complementary data (e.g., as opposed to sequentially pre-reading and writing different values of target data and complementary data) may provide for significantly reduced write times for the differential memory system. For example, the techniques described herein may enable write times for the differential system to be reduced by approximately 15% to approximately 29% or greater. In some implementations, the reduced write times may be achieved with minimal to no increase in the complexity of the differential memory system.

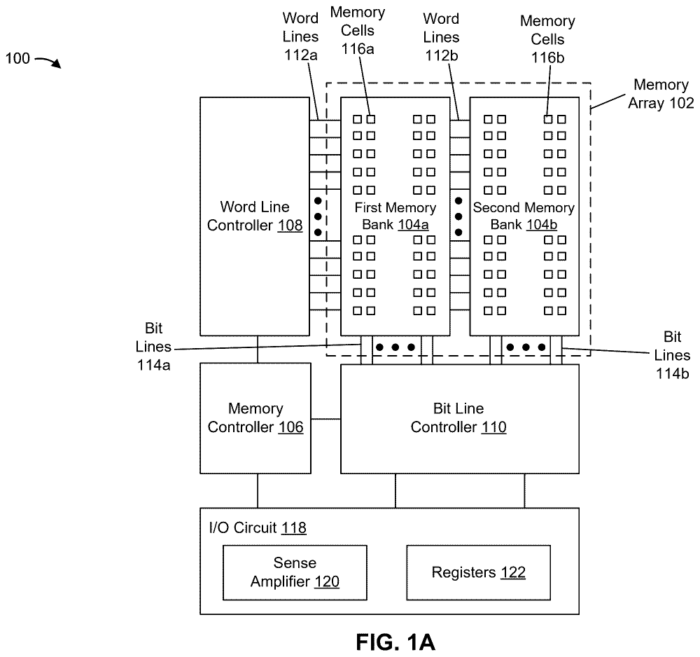

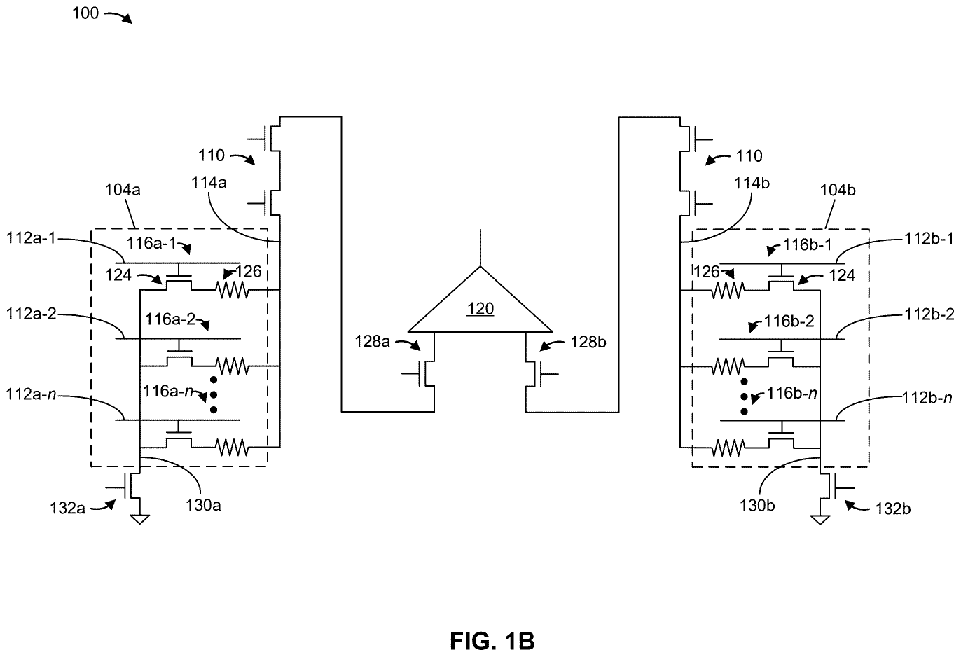

FIGS. 1A and 1B are diagrams of an example memory system 100 described herein.

The memory system 100 may be a standalone memory system, or may be included in another system such as a processing system. Additionally and/or alternatively, the memory system 100 may be included in an electronic device such as a system on chip (SoC), a graphics processing unit (GPU), a high bandwidth memory (HBM) chip, and/or another type of electronic device.

As shown in FIG. 1A, the memory system 100 may include a memory array 102. The memory array 102 may be a differential memory array that includes a first memory bank 104a and a second memory bank 104b. In some implementations, the first memory bank 104a is a target memory bank that includes a first plurality of memory cells configured to store target data, and the second memory bank 104b is a complementary memory bank that includes a second plurality of memory cells configured to store reference data.

“Target data” refers to binary data (e.g., 1-values and/or 0-values) that is to be stored by the memory system 100 and that is utilized by a host system associated with the memory system 100 such as an electronic device 500 described herein. “Reference data” refers to binary data that is used by the memory system 100 and/or the host system to verify the target data and/or to perform error correction for the target data. In some implementations, the reference data stored in the second memory bank 104b is complementary data that includes complementary binary values of the binary values of the target data. For example, one bit of target data may include a 1-value, and a corresponding bit of complementary data may include a 0-value. In some implementations, the reference data stored in the second memory bank 104b is redundant data that is a like-value copy of the target data. For example, one bit of target data may include a 1-value, and a corresponding bit of redundant data may also include a 1-value.

As further shown in FIG. 1A, the memory array 102 may be coupled to one or more controllers of the memory system 100. The controller(s) may be configured to read data from the memory array 102, write data to the memory array 102, and/or perform one or more other operations associated with the memory array 102. The controller(s) may include memory controller 106, a word line controller 108, and/or a bit line controller 110, among other examples. The memory controller 106 may control the operation of the word line controller 108 and/or the operation of the bit line controller 110. In some implementations, the memory controller 106 is implemented as an integrated circuit configured to perform timing functions, tracking functions, and/or control functions, among other examples.

The word line controller 108 and the bit line controller 110 may each include various types of integrated circuits such as decoder circuits, multiplexer circuits, buffer circuits, and/or addressing circuits, among other examples. The word line controller 108 may be communicatively coupled to the first memory bank 104a by a plurality of word lines 112a, and to the second memory bank 104b by a plurality of word lines 112b. The word lines 112a and 112b may be implemented by conductive traces, metal routing, and/or other types of conductive structures. The bit line controller 110 may be communicatively coupled to the first memory bank 104a by a plurality of bit lines 114a, and to the second memory bank 104b by a plurality of word lines 112b. The bit lines 114a and 114b may implemented by conductive traces, metal routing, and/or other types of conductive structures.

Memory cells 116a (e.g., target memory cells) of the first memory bank 104a may be located at intersections of the word lines 112a and the bit lines 114a. The memory cells 116a may be arranged in a plurality of rows (each of the memory cells 116a in a row coupled to the same word line 112a) and a plurality of columns (each of the memory cells 116a in a column coupled to the same bit line 114a). Thus, each memory cell 116a may be coupled to a unique combination of a particular word line 112a and a particular bit line 114a so that each memory cell 116a can be independently addressed through the combination of the word line 112a and the bit line 114a. To address a particular memory cell 116a, the memory controller 106 may use the word line controller 108 to select the word line 112a coupled to the memory cell 116a, and may use the bit line controller 110 to select the bit line 114a coupled to the memory cell 116a.

Similarly, memory cells 116b (e.g., reference memory cells or complementary memory cells) of the second memory bank 104b may be located at intersections of the word lines 112b and the bit lines 114b. The memory cells 116b may be arranged in a plurality of rows (each of the memory cells 116b in a row coupled to the same word line 112b) and a plurality of columns (each of the memory cells 116b in a column coupled to the same bit line 114b). Thus, each memory cell 116b may be coupled to a unique combination of a particular word line 112b and a particular bit line 114b so that each memory cell 116b can be independently addressed. To address a particular memory cell 116b, the memory controller 106 may use the word line controller 108 to select the word line 112b coupled to the memory cell 116b, and may use the bit line controller 110 to select the bit line 114b coupled to the memory cell 116b.

The memory cells 116a and 116b may be implemented as various types of volatile and/or non-volatile memory cell structures. In some implementations, one or more of the memory cells 116a and/or 116b are implemented as one transistor and one capacitor (1T-1C) dynamic random access memory (DRAM) cells. In some implementations, one or more of the memory cells 116a and/or 116b are implemented as floating point transistor (e.g., FLASH memory) cells. In some implementations, one or more of the memory cells 116a and/or 116b are implemented as resistive random access memory (RRAM) cells. In some implementations, one or more of the memory cells 116a and/or 116b are implemented as phase change memory (PCM) cells. In some implementations, one or more of the memory cells 116a and/or 116b are implemented as one transistor and magnetic random access memory (MRAM) cells. In some implementations, one or more of the memory cells 116a and/or 116b are implemented as one transistor and ferroelectric random access memory (FRAM) cells.

As further shown in FIG. 1A, the memory system 100 may further include an I/O circuit 118 coupled to one or more of the memory controller 106, the word line controller 108, and/or the bit line controller 110, among other examples. The I/O circuit 118 may include one or more integrated circuits that are configured to (and/or that are to be used by the memory controller 106 to) transfer data into and/or out of the memory system 100. For example, data to be written to the memory array 102 may be staged or temporarily stored in the I/O circuit 118 so that the memory controller 106 can write the data do the memory array 102. As another example, data to be transferred out of the memory array 102 (e.g., and to a host system) may be transferred to and temporarily stored in the I/O circuit 118.

The I/O circuit 118 may include one or more sense amplifiers 120 that are configured to determine the values to be read from or written to the memory array 102 (e.g., using the bit lines 114a and/or 114b). For example, in a selected string of memory cells 116a, a sense amplifier 120 may read a logic level in a memory cells 116a in response to a read current flowing through the selected string to a bit line 114a. The I/O circuit 118 may further include a plurality of registers 122, which may be used as a data buffer or page buffer for temporarily storing data (e.g., target data, complementary data, redundant data) that is to be written to or read from the memory array 102.

FIG. 1B illustrates a detailed view of a portion of the memory system 100 that includes a sense amplifier 120, a portion of the first memory bank 104a, and a portion of the second memory bank 104b. The portion of the first memory bank 104a includes a subset of memory cells 116a-1 through 116a-n that are coupled to the same bit line 114a and that are respectively coupled to an associated (e.g., a different) word line 112a-1 through 112a-n. The portion of the second memory bank 104b includes a subset of memory cells 116b-1 through 116b-n that are coupled to the same bit line 114b and that are respectively coupled to an associated (e.g., a different) word line 112b-1 through 112b-n.

In the example shown in FIG. 1B, the memory cells 116a-1 through 116a-n and the memory cells 116b-1 through 116b-n are implemented as RRAM cells that each include an access transistor 124 and a resistive storage element 126. The access transistor 124 of a memory cell may provide access to the resistive storage element 126, which may selectively store a binary value (e.g., a 1-value or a 0-value) based on the electrical resistivity of the resistive storage element 126. For example, a high resistive state may correspond to a 0-value and a low resistive state may correspond to a 1-value. However, as indicated above, the memory cells 116a-1 through 116a-n and/or the memory cells 116b-1 through 116b-n may be implemented by other types of memory cell structures.

As further shown in FIG. 1B, the memory cells 116a-1 through 116a-n may be coupled to the bit line 114a through the bit line controller 110 and a column transistor 128a, and the memory cells 116b-1 through 116b-may be coupled to the bit line 114b through the bit line controller 110 and a column transistor 128b. The memory cells 116a-1 through 116a-n may be coupled a select line 130a through a select transistor 132a, and the memory cells 116b-1 through 116b-n may be coupled a select line 130b through a select transistor 132b.

As indicated above, FIGS. 1A and 1B are provided as an example. Other examples may differ from what is described with regard to FIGS. 1A and 1B.

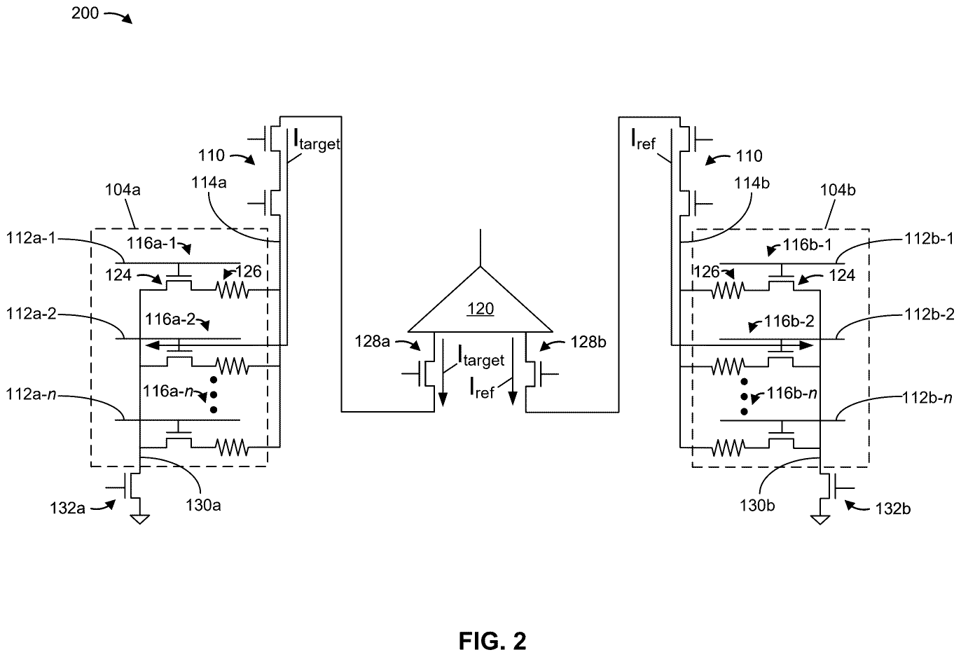

FIG. 2 is a diagram of an example implementation 200 of a write operation for writing differential data to the memory array 102 of the memory system 100 described herein. The write operation may specifically include a write operation to write target data to the first memory bank 104a and reference data (e.g., complementary data, redundant data) to the second memory bank 104b.

As shown in FIG. 2, the write operation may include providing a target current (I_{target}) from the sense amplifier 120 to the memory cell 116a-2 through the bit line controller 110 and the bit line 114a. The flow path for the target current may be provided through the column transistor 128a. The word line 112a-2 may be activated to electrically coupled the memory cell 116a-2 to the select line 130a.

Similarly, the write operation may include providing a reference current (I_{ref}) from the sense amplifier 120 to the memory cell 116b-2 through the bit line controller 110 and the bit line 114b. The flow path for the target current may be provided through the column transistor 128b. The word line 112b-2 may be activated to electrically coupled the memory cell 116b-2 to the select line 130b.

In some implementations, the write operation includes writing a 1-value to the memory cell 116a-2 for target data to be stored in the memory cell 116a-2, and writing a complementary 0-value to the memory cell 116b-2 for complementary data to be stored in the memory cell 116b-2 for the target data. In these implementations, the resistive storage element 126 of the memory cell 116a-2 may be programmed into a low resistance state for the 1-value, and the resistive storage element 126 of the memory cell 116b-2 may be programmed into a high resistance state for the 0-value.

In some implementations, the write operation includes writing a 1-value to the memory cell 116a-2 for target data to be stored in the memory cell 116a-2, and writing a redundant 1-value to the memory cell 116b-2 for redundant data to be stored in the memory cell 116b-2 for the target data. In these implementations, the resistive storage element 126 of the memory cell 116a-2 may be programmed into a low resistance state for the 1-value, and the resistive storage element 126 of the memory cell 116b-2 may also be programmed into a low resistance state for the redundant 1-value.

As indicated above, FIG. 2 is provided as an example. Other examples may differ from what is described with regard to FIG. 2.

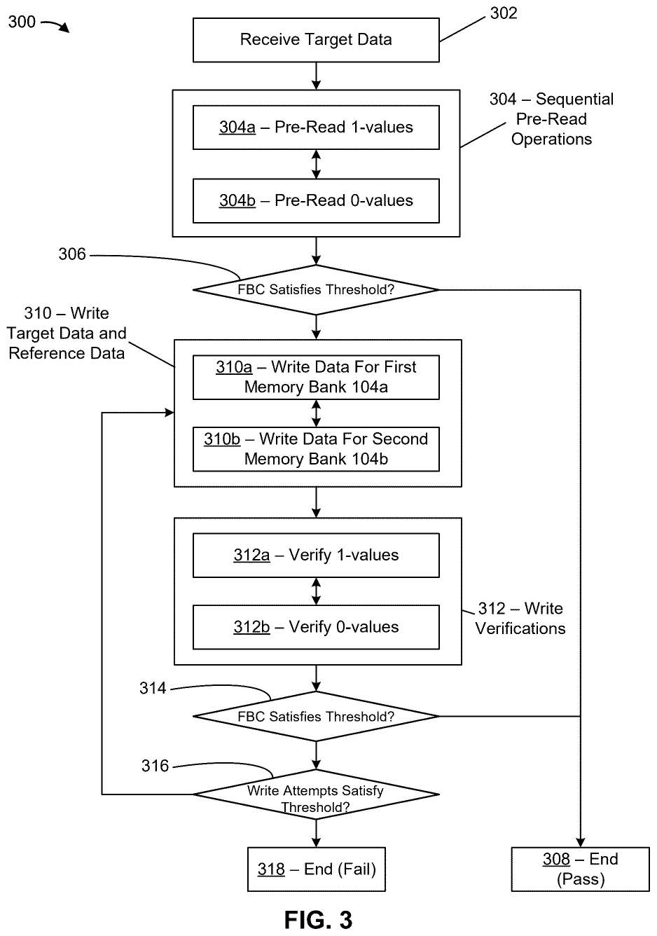

FIG. 3 is a diagram of an example implementation 300 of writing differential data to the memory array 102 of the memory system 100 described herein. At 302, the memory system 100 may receive target data that is to be written to the memory array 102. The target data may be stored in one or more registers 122 of the I/O circuit 118.

In some implementations, reference data for the target data is also stored in one or more registers 122. The reference data in the example implementation 300 may correspond to complementary data for the target data. Accordingly, the target data and the complementary data may be stored in different registers 122. For example, the target data may be stored in one or more target data registers, and the reference data may be stored in one or more reference data registers (e.g., complementary data registers).

In some implementations, the memory system 100 receives the reference data along with the target data (e.g., from a host system). In some implementations, the memory controller 106 may provide one or more signals to the I/O circuit 118 to cause the reference data to be generated from the target data, which may include generating complementary binary values of the binary values of the target data.

At 304, the memory controller 106 may sequentially perform pre-read operations for the target data and the reference data in the registers 122. A pre-read operation may include the memory controller 106 reading the data stored in the memory cells 116a of the first memory bank 104a and the data stored in the memory cells 116b of the second memory bank 104b, and determining, based on the target data and the reference data, which of the memory cells 116a and the memory cells 116b are to be written to for the write operation. The determination by the memory controller 106 may be based on determining that one or more memory cells 116a are storing values different from the values in the target data, and/or based on determining that one or more memory cells 116b are storing values different from the values in the reference data.

The memory controller 106 may perform the pre-read operations for the target data and the reference data in sequential pre-read operations for 1-values of the target data and the reference data, and for 0-values of the target data and the reference data. For example, the memory controller 106 may perform a first pre-read operation for the 1-values of target data and the 1-values of the reference data at 304a in the registers 122, and the memory controller 106 may perform a second pre-read operation for the 0-values of the target data and the 0-values reference data in the registers 122 at 304b after the pre-read operation for the 1-values. As another example, the memory controller 106 may perform a first pre-read operation for the 0-values of target data and the 0-values of the reference data in the registers 122 at 304b, and the memory controller 106 may perform a second pre-read operation for the 1-values of the target data and the 1-values reference data in the registers 122 at 304b after the pre-read operation for the 0-values.

Performing the pre-read operation at 304a for the 1-values of target data and the 1-values of reference data may include reading the memory cells 116a and 116b in which the 1-values are to be stored and comparing the values in those memory cells to the 1-values of the target data and the reference data in the registers 122. Performing the pre-read operation at 304b for the 0-values of target data and the 0-values of reference data may include reading the memory cells 116a and 116b in which the 0-values are to be stored and comparing the values in those memory cells to the 0-values of the target data and the reference data in the registers.

The memory controller 106 may generate write masks for the target data (R_MASK) and for the reference data (R_CMASK) based on pre-reading the target data and pre-reading the reference data, respectively. The target data mask may include a write mask that is used to control which bits and/or bytes within a word of the target data in the registers 122 are to be written to the first memory bank 104a for the write operation. The target data mask may include unmasked bits and masked bits for the memory cells 116a of the first memory bank 104a. The unmasked bits correspond to memory cells 116a of the first memory bank 104a to which the target data is to be written, whereas the masked bits correspond to memory cells 116a that are not to be written to in the write operation. In other words, the unmasked bits correspond to the memory cells 116a of the first memory bank 104a that will be programmed in the write operation, and the masked bits correspond to memory cells 116a that will retain target data already programmed from another write operation.

The reference data mask may include a write mask that is used to control which bits and/or bytes within a word of the reference data in the registers 122 are to be written to the second memory bank 104b for the write operation. The reference data mask may include unmasked bits and masked bits for the memory cells 116b of the second memory bank 104b. The unmasked bits correspond to memory cells 116b of the second memory bank 104b to which the reference data is to be written, whereas the masked bits correspond to memory cells 116b that are not to be written to in the write operation. In other words, the unmasked bits correspond to the memory cells 116b of the second memory bank 104b that will be programmed in the write operation, and the masked bits correspond to memory cells 116b that will retain reference data already programmed from another write operation.

At 306, the memory controller 106 may determine whether a fail bit count (FBC) for the pre-read operations satisfies a threshold. For example, the memory controller 106 may determine if the quantity of bits, in the target data that is different from the data stored in the memory cells 116a to which the target data is to be written, is greater than 0. Similarly, the memory controller 106 may determine if the quantity of bits, in the reference data that is different from the data stored in the memory cells 116b to which the reference data is to be written, is greater than 0. If each of the quantities is greater than 0, the memory controller 106 may proceed with writing the target data to the first memory bank 104a and writing the reference data to the second memory bank 104b. If the quantities are each 0, the memory controller 106 may end the write process at 308.

The memory controller 106 may determine whether the FBCs for the target data and for the reference data are greater than 0 based on the write masks for the target data and the reference data. For example, if the write mask for the target data contains all masked values (e.g., no memory cells 116a are to be written to), the memory controller 106 may determine that the FBC for the target data is 0. As another example, if the write mask for the target data contains one or more unmasked values (e.g., one or more memory cells 116a are to be written to), the memory controller 106 may determine that the FBC for the target data is greater than 0.

At 310, as part of the write process, the memory controller 106 may write the target data to the first memory bank 104a and may write the reference data to the second memory bank 104b based on determining that the FBCs for the target data and for the reference data satisfy the threshold (e.g., are greater than 0). The memory controller 106 may write the target data to the first memory bank 104a and may write the reference data to the second memory bank 104b after performing the pre-read operations for both the target data and the reference data. Batching together the pre-reads for the target data and the reference data (e.g., as opposed to sequentially pre-reading and writing different values of target data and reference data) may provide for significantly reduced write times for writing the target and the reference data for the memory system 100 because the quantity of read operations to verify the written data is reduced from 4*(1+N) write operations to 2+2*N read operations.

As shown in FIG. 3, writing the target data and the reference data may include writing the target data to the unmasked memory cells 116a (e.g., based on the write mask for the target data) of the first memory bank 104a at 310a, and writing the reference data to the unmasked memory cells 116b (e.g., based on the write mask for the reference data) of the second memory bank 104b at 310b. The memory controller 106 may write a binary value of the target data to a memory cell 116a, and may write an associated binary value of the reference data to a memory cell 116b, by performing operations described in connection with example write operation illustrated and described in FIG. 2.

In some implementations, the memory controller 106 performs a first write operation to write the target data to the unmasked memory cells 116a of the first memory bank 104a at 310a (e.g., based on the write mask for the target data), and performs a second write operation to write the reference data to the unmasked memory cells 116b (e.g., based on the write mask for the reference data) of the second memory bank 104b at 310b after the first write operation. The memory controller 106 may perform the first write operation by writing the 1-values and the 0-values of the target data to the memory cells 116a at 310a, and may perform the second write operation by writing the 1-values and the 0-values of the reference data to the memory cells 116b at 310b.

In some implementations, the memory controller 106 performs a first write operation to write the target data to the unmasked memory cells 116a of the first memory bank 104a at 310a, and performs a second write operation to write the reference data to the unmasked memory cells 116b (e.g., based on the write mask for the reference data) of the second memory bank 104b at 310b after the first write operation.

The unmasked memory cells 116a are memory cells that are counted as part of the FBC for the first memory bank 104a, and writing the 1-values and the 0-values of the target data to the unmasked memory cells 116a corrects the failed bits that are part of the FBC for the first memory bank 104a. Similarly, the unmasked memory cells 116b are memory cells that are counted as part of the FBC for the second memory bank 104b, and writing the 1-values and the 0-values of the reference data to the unmasked memory cells 116b corrects the failed bits that are part of the FBC for the second memory bank 104b.

At 312, the memory controller 106 may perform write verifications for the target data written to the memory cells 116a of the first memory bank 104a, and for the reference data written to the memory cells 116b of the second memory bank 104b. In some implementations, the memory controller 106 verifies the target data and the reference data by binary value. For example, at 312a, the memory controller 106 may verify the 1-values of the target data that were written to the memory cells 116a of the first memory bank 104a and the 1-values of the reference data that were written to the memory cells 116b of the second memory bank 104b. As another example, at 312b, the memory controller 106 may verify the 0-values of the target data that were written to the memory cells 116a of the first memory bank 104a and the 0-values of the reference data that were written to the memory cells 116b of the second memory bank 104b.

In some implementations, the memory controller 106 performs a first read operation to verify the write operations for the 1-values of the target data and of the reference data at 312a, and the memory controller 106 performs a second read operation to verify the write operations for the 0-values of the target data and of the reference data at 312b after the first read operation. In some implementations, the memory controller 106 performs a first read operation to verify the write operations for the 0-values of the target data and of the reference data at 312b, and the memory controller 106 performs a second read operation to verify the write operations for the 1-values of the target data and of the reference data at 312a after the first read operation.

To verify the target data written to the memory cells 116a of the first memory bank 104a, the memory controller 106 may perform read operations to read the target data that was written to the memory cells 116a of the first memory bank 104a at 310 (e.g., at 310a), and may compare the target data read from the memory cells 116a of the first memory bank 104a with the target data stored in the registers 122. This is similar to the pre-read operation for the 1-values and 0-values of the target data performed at 304.

To verify the reference data written to the memory cells 116b of the second memory bank 104b, the memory controller 106 may perform read operations to read the reference data that was written to the memory cells 116b of the second memory bank 104b at 310 (e.g., at 310b), and may compare the reference data read from the memory cells 116b of the second memory bank 104b with the reference data stored in the registers 122. This is similar to the pre-read operation for the 1-values and 0-values of the reference data performed at 304.

At 314, the memory controller 106 may determine whether the FBC for the target data written into the memory cells 116a satisfies a threshold. Similarly, the memory controller 106 may determine whether the FBC for the reference data written into the memory cells 116b satisfies a threshold. In other words, the memory controller 106 compares the target data in the memory cells 116a with the target data in the registers 122 to determine if any write errors occurred in the write operation for the target data (e.g., if the FBC for the target data is greater than 0), and compares the reference data in the memory cells 116b with the reference data in the registers 122 to determine if any write errors occurred in the write operation for the reference data (e.g., if the FBC for the reference data is greater than 0). This may include generating updated write masks for the target data and the reference data in the registers 122, and determining if the write masks for either the target data or the reference data contain any unmasked memory cells.

If the memory controller 106 determines that the FBCs for the target data and for the reference data are 0, the memory controller 106 may end the write process at 308 successfully. If the memory controller 106 determines that one or more of the FBCs for the target data or for the reference data are greater than 0, the memory controller 106 may determine whether the quantity of write attempts for the target data and the reference data in the registers 122 satisfies a threshold at 316. If the memory controller 106 determines that the quantity of write attempts for the target data and the reference data in the registers 122 satisfies a threshold (e.g., the quantity of attempts is greater than or equal to an allowed quantity of attempts), the memory controller 106 may end the write operation at 318 and may determine that the write operation failed.

If the memory controller 106 determines that the quantity of write attempts for the target data and the reference data in the registers 122 does not satisfy the threshold (e.g., the quantity of attempts is less than the allowed quantity of attempts), the memory controller 106 use the updated write masks for the target data and for the reference data to perform another write attempt to write the target data and the reference data to the memory array 102. This may include rewriting only the unmasked memory cells 116a and only the unmasked memory cells 116b at 310a and 310b, respectively, and performing another set of verification operations to verify the write attempt at 312a, 312b, and 314.

As indicated above, FIG. 3 is provided as an example. Other examples may differ from what is described with regard to FIG. 3.

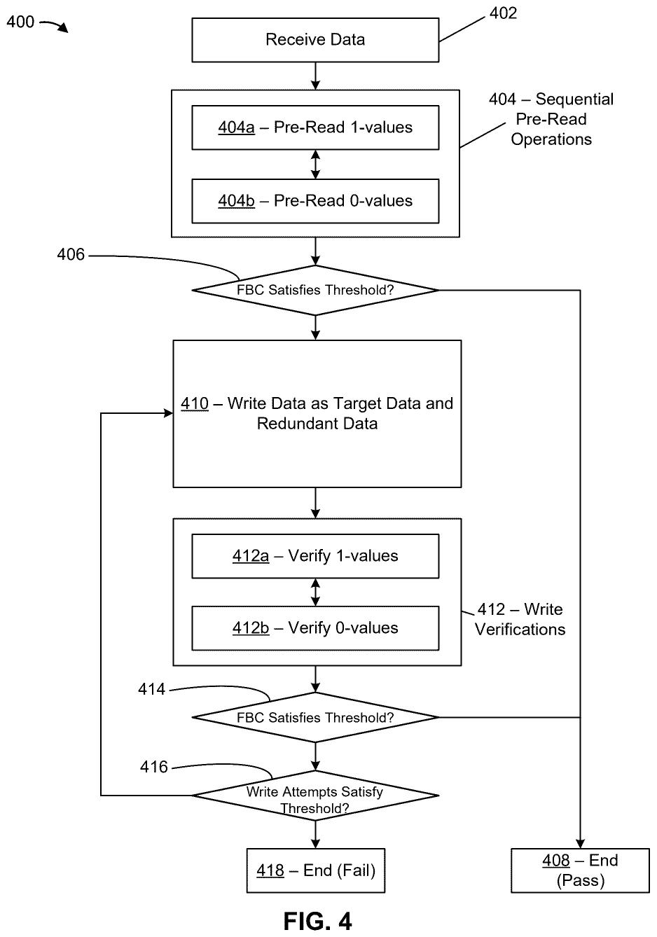

FIG. 4 is a diagram of an example implementation 400 of writing differential data to the memory array 102 of the memory system 100 described herein. The example implementation 400 is similar to the example implementation 300, except that the reference data in the example implementation 400 may correspond to redundant data for the target data. Thus, because the redundant data and the target data are the same binary values (e.g., the reference data for a 1-value of target data is also a 1-value of redundant data as opposed to being a 0-value of complementary data), only a single set of data is stored in the registers 122 for the target data and the reference data. In other words, the target data and the reference data stored in the registers 122 are the same dataset.

At 402, the memory system 100 may receive the data (which may be used as the target data and the reference data) in the registers 122 (e.g., from a host system).

At 404 the memory controller 106 may perform pre-read operations for the data. A pre-read operation may include the memory controller 106 reading the target data stored in the memory cells 116a of the first memory bank 104a and the redundant data stored in the memory cells 116b of the second memory bank 104b, and determining, based on the target data and the redundant data, which of the memory cells 116a and the memory cells 116b are to be written to for the write operation. The determination by the memory controller 106 may be based on determining that one or more memory cells 116a and one or more memory cells 116b are storing values different from the values of the data in the registers 122.

The memory controller 106 may sequentially perform pre-read operations for the 1-values for the data in the registers 122, and for the 0-values of the data in the registers 122. For example, the memory controller 106 may perform a first pre-read operation for the 1-values of the data in the registers 122 at 404a, and may perform a second pre-read operation for the 0-values of the data in the registers 122 at 404b after the pre-read operation for the 1-values. As another example, the memory controller 106 may perform a first pre-read operation the 0-values for the data in the registers 122 at 404b, and the memory controller 106 may perform a second pre-read operation for the 1-values of the data in the registers 122 at 404a after the pre-read operation for the 0-values.

Performing the pre-read operation at 404a for the 1-values of the data in the registers 122 may include reading the target data stored in the memory cells 116a and reading the reference data (e.g., the redundant data) stored in the memory cells 116b in which the 1-values of the data are to be stored, and comparing the values in those memory cells to the 1-values of the data in the registers 122. Performing the pre-read operation at 404b for the 0-values of the data in the registers 122 may include reading the target data stored in the memory cells 116a and reading the reference data (e.g., the redundant data) stored in the memory cells 116b in which the 0-values of the data are to be stored, and comparing the values in those memory cells to the 0-values of the data in the registers 122.

The memory controller 106 may generate a write mask (e.g., a single write mask R_MASK) that is to be used for writing the data as target data in the memory cells 116a of the first memory bank 104a, and for writing the data as reference data (e.g., redundant data) in the memory cells 116b of the second memory bank 104b. The write mask may be used to control which bits and/or bytes within a word of the data in the registers 122 are to be written to the first memory bank 104a and to the second memory bank 104b for the write operation. The write mask may include unmasked bits and masked bits for both the first memory bank 104a and the second memory bank 104b. The unmasked bits correspond to memory cells 116a of the first memory bank 104a to which the data in the registers 122 is to be written as target data, and to memory cells 116b of the second memory bank 104b to which the data in the registers 122 is to be written as reference data (e.g., redundant data). The masked bits correspond to memory cells 116a and 116b that are not to be written to in the write operation.

At 406, the memory controller 106 may determine whether the FBCs for the pre-read operations satisfies a threshold. For example, the memory controller 106 may determine if the quantity of bits, in the data in registers 122 that is different from the data stored in the memory cells 116a to which the data is to be written as target data, is greater than 0. Similarly, the memory controller 106 may determine if the quantity of bits, in the data in the registers 122 that is different from the data stored in the memory cells 116b to which the data is to be written as reference data, is greater than 0. If each of the quantities is greater than 0, the memory controller 106 may proceed with writing the data to the first memory bank 104a as target data, and writing the data to the second memory bank 104b as reference data. If the quantities are each 0, the memory controller 106 may end the write process at 408.

At 410, as part of the write process, the memory controller 106 may write the data from the registers 122 to the first memory bank 104a as target data, and may write the data from the registers 122 to the second memory bank 104b as reference data, based on determining that the FBCs satisfy the threshold (e.g., are greater than 0). The memory controller 106 may write the data to the first memory bank 104a and may write the data to the second memory bank 104b after performing the pre-read operations for both the first memory bank 104a and the second memory bank 104b. Batching together the pre-reads for the binary values of the data in the registers 122 for both the first memory bank 104a and the second memory bank 104b (e.g., as opposed to sequentially pre-reading and writing different values of the data to the first memory bank 104a and the second memory bank 104b) may provide for significantly reduced write times for writing the target and the reference data for the memory system 100.

Writing the data may include simultaneously writing the 1-values and 0-values of the data in the registers 122 to the unmasked memory cells 116a of the first memory bank 104a and writing the data in the registers 122 to the unmasked memory cells 116b of the second memory bank 104b based on the write mask. Alternatively, the memory controller 106 may sequentially write the 1-values and the 0-values of the data. The memory controller 106 may write a binary value of the data to a memory cell 116a as target data, and may write the same binary value to an associated memory cell 116b as reference data, by performing operations described in connection with example write operation illustrated and described in FIG. 2.

At 412, the memory controller 106 may perform write verifications for the target data written to the memory cells 116a of the first memory bank 104a, and for the reference data written to the memory cells 116b of the second memory bank 104b. In some implementations, the memory controller 106 verifies the target data and the reference data by binary value. For example, at 412a, the memory controller 106 may verify the 1-values of the target data that were written to the memory cells 116a of the first memory bank 104a and the 1-values of the reference data that were written to the memory cells 116b of the second memory bank 104b. As another example, at 412b, the memory controller 106 may verify the 0-values of the target data that were written to the memory cells 116a of the first memory bank 104a and the 0-values of the reference data that were written to the memory cells 116b of the second memory bank 104b.

In some implementations, the memory controller 106 performs a first read operation to verify the write operations for the 1-values of the target data and of the reference data at 412a, and the memory controller 106 performs a second read operation to verify the write operations for the 0-values of the target data and of the reference data at 412b after the first read operation. In some implementations, the memory controller 106 performs a first read operation to verify the write operations for the 0-values of the target data and of the reference data at 412b, and the memory controller 106 performs a second read operation to verify the write operations for the 1-values of the target data and of the reference data at 412a after the first read operation.

At 414, the memory controller 106 may determine whether the FBC for the target data written into the memory cells 116a satisfies a threshold. Similarly, the memory controller 106 may determine whether the FBC for the reference data written into the memory cells 116b satisfies a threshold. In other words, the memory controller 106 compares the target data in the memory cells 116a with the data in the registers 122 to determine if any write errors occurred in the write operation for the target data (e.g., if the FBC for the target data is greater than 0), and compares the reference data in the memory cells 116b with the data in the registers 122 to determine if any write errors occurred in the write operation for the reference data (e.g., if the FBC for the reference data is greater than 0). This may include generating an updated write mask for the data in the registers 122, and determining if the write mask for either the target data or the reference data contain any unmasked memory cells.

If the memory controller 106 determines that the FBCs for the target data and for the reference data are 0, the memory controller 106 may end the write process at 408 successfully.

If the memory controller 106 determines that one or more of the FBCs for the target data or for the reference data are greater than 0, the memory controller 106 may determine whether the quantity of write attempts for the data in the registers 122 satisfies a threshold at 416. If the memory controller 106 determines that the quantity of write attempts for the data in the registers 122 satisfies a threshold (e.g., the quantity of attempts is greater than or equal to an allowed quantity of attempts), the memory controller 106 may end the write operation at 418 and may determine that the write operation failed.

If the memory controller 106 determines that the quantity of write attempts for the data in the registers 122 does not satisfy the threshold (e.g., the quantity of attempts is less than the allowed quantity of attempts), the memory controller 106 use the updated write mask to perform another write attempt to write the data to the memory array 102. This may include rewriting only the unmasked memory cells 116a and only the unmasked memory cells 116b at 410, and performing another set of verification operations to verify the write attempt at 412a, 412b, and 414.

As indicated above, FIG. 4 is provided as an example. Other examples may differ from what is described with regard to FIG. 4.

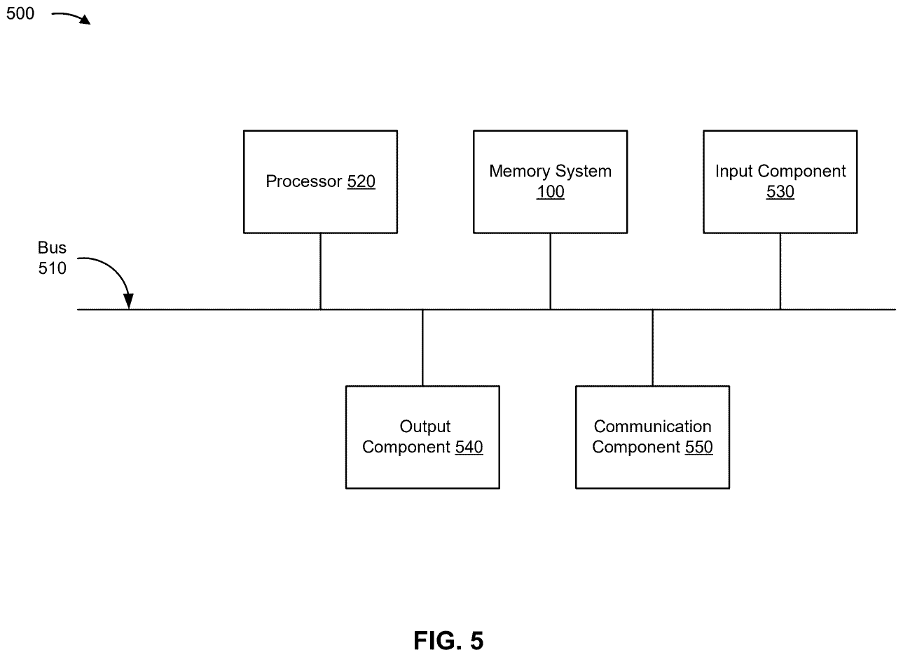

FIG. 5 is a diagram of example components of an electronic device 500 described herein. The electronic device 500 may be a mobile phone (e.g., a smartphone), a tablet device, a computer (e.g., a laptop computer, a desktop computer), a data center server, a cloud computing device, an IoT device, and/or another type of electronic device that includes one or more memory systems 100. In the example shown in FIG. 5, the electronic device 500 includes a bus 510, a processor 520, the memory system 100, an input component 530, an output component 540, and/or a communication component 550.

The bus 510 includes one or more components that enable wired and/or wireless communication among the components of the electronic device 500. The bus 510 couples together two or more components of FIG. 5, such as via operative coupling, communicative coupling, electronic coupling, and/or electric coupling. For example, the bus 510 may include an electrical connection (e.g., a wire, a trace, and/or a lead) and/or a wireless bus.

The processor 520 includes a central processing unit (CPU), a GPU, a microprocessor, a controller, a microcontroller, a digital signal processor, a field-programmable gate array (FPGA), an application-specific integrated circuit (ASIC), and/or another type of processing component. The processor 520 may be implemented in hardware, firmware, or a combination of hardware and software. In some implementations, the processor 520 includes one or more processors capable of being programmed to perform one or more operations or processes described elsewhere herein.

The memory system 100 includes volatile and/or nonvolatile memory. In some implementations, the memory system 100 is or includes a non-transitory computer-readable medium. The memory system 100 may store information, one or more instructions, and/or software (e.g., one or more software applications) related to the operation of the electronic device 500.

In some implementations, the memory system 100 includes one or more memories that are coupled (e.g., communicatively coupled) to one or more processors (e.g., processor 520), such as via the bus 510. Communicative coupling between a processor 520 and the memory system 100 enables the processor 520 to read and/or process information stored in the memory system 100 and/or to store information in the memory system 100. In some implementations, the memory system 100 is embedded in the processor 520. For example, the processor 520 may be a GPU that includes one or more compute chips and one or more HBM chips (corresponding to the memory system 100).

The input component 530 enables the electronic device 500 to receive input, such as user input and/or sensed input. For example, the input component 530 may include a touch screen, a keyboard, a keypad, a mouse, a button, a microphone, a switch, a sensor, a global positioning system sensor, a global navigation satellite system sensor, an accelerometer, a gyroscope, and/or an actuator. The output component 540 enables the electronic device 500 to provide output, such as via a display, a speaker, and/or a light-emitting diode. The communication component 550 enables the electronic device 500 to communicate with other devices via a wired connection and/or a wireless connection. For example, the communication component 550 may include a receiver, a transmitter, a transceiver, a modem, a network interface card, and/or an antenna.

In some implementations, the electronic device 500 performs one or more operations or processes described herein. For example, a non-transitory computer-readable medium (e.g., the memory system 100) may store a set of instructions (e.g., one or more instructions or code) for execution by the processor 520. The processor 520 may execute the set of instructions to perform one or more operations or processes described herein. In some implementations, execution of the set of instructions, by one or more processors 520, causes the one or more processors 520 and/or the electronic device 500 to perform one or more operations or processes described herein. In some implementations, hardwired circuitry is used instead of or in combination with the instructions to perform one or more operations or processes described herein. Additionally, or alternatively, the processor 520 may be configured to perform one or more operations or processes described herein. Thus, implementations described herein are not limited to any specific combination of hardware circuitry and software.

The number and arrangement of components shown in FIG. 5 are provided as an example. The electronic device 500 may include additional components, fewer components, different components, or differently arranged components than those shown in FIG. 5. Additionally, or alternatively, a set of components (e.g., one or more components) of the electronic device 500 may perform one or more functions described as being performed by another set of components of the electronic device 500.

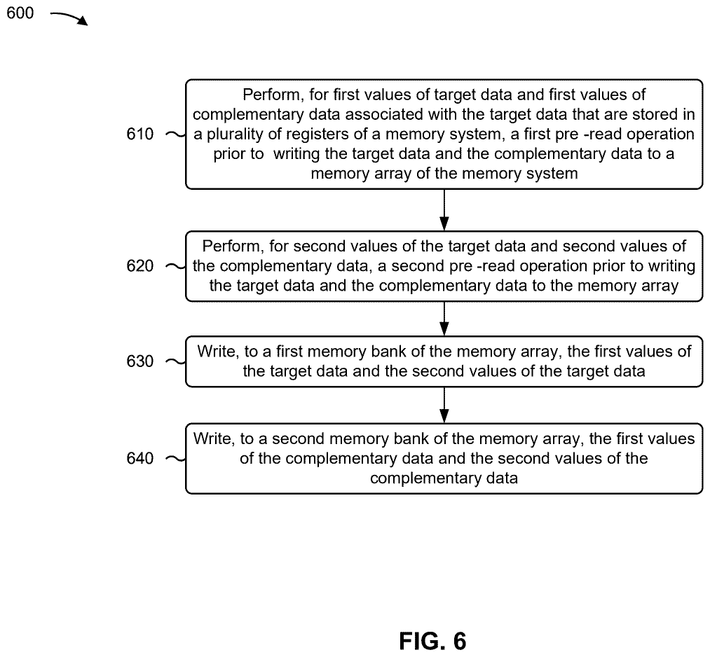

FIG. 6 is a flowchart of an example process 600 associated with writing data to a memory array in a differential memory system described herein. One or more process blocks of FIG. 6 are performed by a differential memory system (e.g., the memory system 100) and/or by another device or a group of devices separate from or including the memory system 100, such as the electronic device 500. Additionally, or alternatively, one or more process blocks of FIG. 6 may be performed by one or more components of the electronic device 500, such as the processor 520, the input component 530, the output component 540, and/or communication component 550.

As shown in FIG. 6, process 600 includes performing, for first values of target data and first values of complementary data associated with the target data that are stored in a plurality of registers of a memory system, a first pre-read operation prior to writing the target data and the complementary data to a memory array of the memory system (block 610). For example, the memory system 100 (or the memory controller 106 of the memory system 100) may perform, for first values of target data and first values of complementary data associated with the target data that are stored in a plurality of registers (e.g., registers 122) of the memory system, a first pre-read operation prior to writing the target data and the complementary data to a memory array (e.g., a memory array 102) of the memory system, as described herein.

As further shown in FIG. 6, process 600 includes performing, for second values of the target data and second values of the complementary data, a second pre-read operation prior to writing the target data and the complementary data to the memory array (block 620). For example, the memory system 100 (or the memory controller 106 of the memory system 100) may perform, for second values of the target data and second values of the complementary data, a second pre-read operation prior to writing the target data and the complementary data to the memory array, as described herein.

As further shown in FIG. 6, process 600 includes writing, to a first memory bank of the memory array, the first values of the target data and the second values of the target data (block 630). For example, the memory system 100 (or the memory controller 106 of the memory system 100) may write, to a first memory bank (e.g., a first memory bank 104a) of the memory array, the first values of the target data and the second values of the target data, as described herein.

As further shown in FIG. 6, process 600 includes writing, to a second memory bank of the memory array, the first values of the complementary data and the second values of the complementary data (block 640). For example, the memory system 100 (or the memory controller 106 of the memory system 100) may write, to a second memory bank (e.g., a second memory bank 104b) of the memory array, the first values of the complementary data and the second values of the complementary data, as described herein.

Process 600 may include additional aspects, such as any single aspect or any combination of aspects described below and/or in connection with one or more other processes described elsewhere herein.

In a first implementation, the first values of the target data and the first values of the complementary data include 1-values, and the second values of the target data and the second values of the complementary data include 0-values.

In a second implementation, alone or in combination with the first implementation, performing the first pre-read operation includes performing the first pre-read operation prior to performing the second pre-read operation.

In a third implementation, alone or in combination with one or more of the first and second implementations, performing the first pre-read operation includes performing the second pre-read operation prior to performing the first pre-read operation.

In a fourth implementation, alone or in combination with one or more of the first through third implementations, process 600 includes storing the target data in a first register (e.g., a first register 122) of the plurality of registers.

In a fifth implementation, alone or in combination with one or more of the first through fourth implementations, process 600 includes storing the complementary data in a second register (e.g., a second register 122) of the plurality of registers.

In a sixth implementation, alone or in combination with one or more of the first through fifth implementations, writing the first values of the target data and the second values of the target data includes writing the first values of the target data and the second values of the target data prior to writing the first values of the complementary data and the second values of the complementary data.

In a seventh implementation, alone or in combination with one or more of the first through sixth implementations, writing the first values of the target data and the second values of the target data includes writing the first values of the target data and the second values of the target data after writing the first values of the complementary data and the second values of the complementary data.

Although FIG. 6 shows example blocks of process 600, in some implementations, process 600 includes additional blocks, fewer blocks, different blocks, or differently arranged blocks than those depicted in FIG. 6. Additionally, or alternatively, two or more of the blocks of process 600 may be performed in parallel.

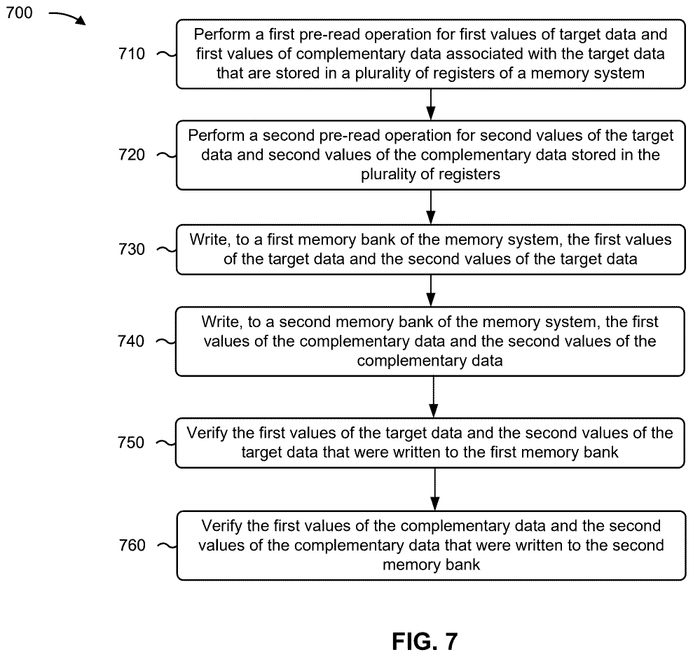

FIG. 7 is a flowchart of an example process 700 associated with writing data to a memory array in a differential memory system described herein. One or more process blocks of FIG. 7 are performed by a differential memory system (e.g., the memory system 100) and/or by another device or a group of devices separate from or including the memory system 100, such as the electronic device 500. Additionally, or alternatively, one or more process blocks of FIG. 7 may be performed by one or more components of the electronic device 500, such as the processor 520, the input component 530, the output component 540, and/or communication component 550.

As shown in FIG. 7, process 700 includes performing a first pre-read operation for first values of target data and first values of complementary data associated with the target data that are stored in a plurality of registers of a memory system (block 710). For example, the memory system 100 (or the memory controller 106 of the memory system 100) may perform a first pre-read operation for first values of target data and first values of complementary data associated with the target data that are stored in the plurality of registers (e.g., registers 122), as described herein.

As further shown in FIG. 7, process 700 includes performing a second pre-read operation for second values of the target data and second values of the complementary data stored in the plurality of registers (block 720). For example, the memory system 100 (or the memory controller 106 of the memory system 100) may perform a second pre-read operation for second values of the target data and second values of the complementary data stored in the plurality of registers, as described herein.

As further shown in FIG. 7, process 700 includes writing, to a first memory bank of the memory system, the first values of the target data and the second values of the target data (block 730). For example, the memory system 100 (or the memory controller 106 of the memory system 100) may write, to a first memory bank (e.g., a first memory bank 104a), the first values of the target data and the second values of the target data, as described herein.

As further shown in FIG. 7, process 700 includes writing, to a second memory bank of the memory system, the first values of the complementary data and the second values of the complementary data (block 740). For example, the memory system 100 (or the memory controller 106 of the memory system 100) may write, to a second memory bank (e.g., a second memory bank 104b) of the memory system, the first values of the complementary data and the second values of the complementary data, as described herein.

As further shown in FIG. 7, process 700 includes verifying the first values of the target data and the second values of the target data that were written to the first memory bank (block 750). For example, the memory system 100 (or the memory controller 106 of the memory system 100) may verify the first values of the target data and the second values of the target data that were written to the first memory bank, as described herein.

As further shown in FIG. 7, process 700 includes verifying the first values of the complementary data and the second values of the complementary data that were written to the second memory bank (block 760). For example, the memory system 100 (or the memory controller 106 of the memory system 100) may verify the first values of the complementary data and the second values of the complementary data that were written to the second memory bank, as described herein.

Process 700 may include additional aspects, such as any single aspect or any combination of aspects described below and/or in connection with one or more other processes described elsewhere herein.

In a first implementation, process 700 includes verifying the first values of the target data prior to verifying the second values of the target data.

In a second implementation, alone or in combination with the first implementation, process 700 includes verifying the first values of the target after verifying the second values of the target data.

In a third implementation, alone or in combination with one or more of the first and second implementations, process 700 includes verifying the first values of the complementary data prior to verifying the second values of the complementary data.

In a fourth implementation, alone or in combination with one or more of the first through third implementations, process 700 includes verifying the first values of the complementary data after verifying the second values of the complementary data.

In a fifth implementation, alone or in combination with one or more of the first through fourth implementations, process 700 includes verifying the first values of the target data that were written to the first memory bank and verify the first values of the complementary data that were written to the second memory bank prior to verifying the second values of the target data that were written to the first memory bank and prior to verifying the second values of the complementary data that were written to the second memory bank.

In a sixth implementation, alone or in combination with one or more of the first through fifth implementations, process 700 includes verifying the first values of the target data that were written to the first memory bank and verify the first values of the complementary data that were written to the second memory bank after verifying the second values of the target data that were written to the first memory bank and after verifying the second values of the complementary data that were written to the second memory bank.

Although FIG. 7 shows example blocks of process 700, in some implementations, process 700 includes additional blocks, fewer blocks, different blocks, or differently arranged blocks than those depicted in FIG. 7. Additionally, or alternatively, two or more of the blocks of process 700 may be performed in parallel.

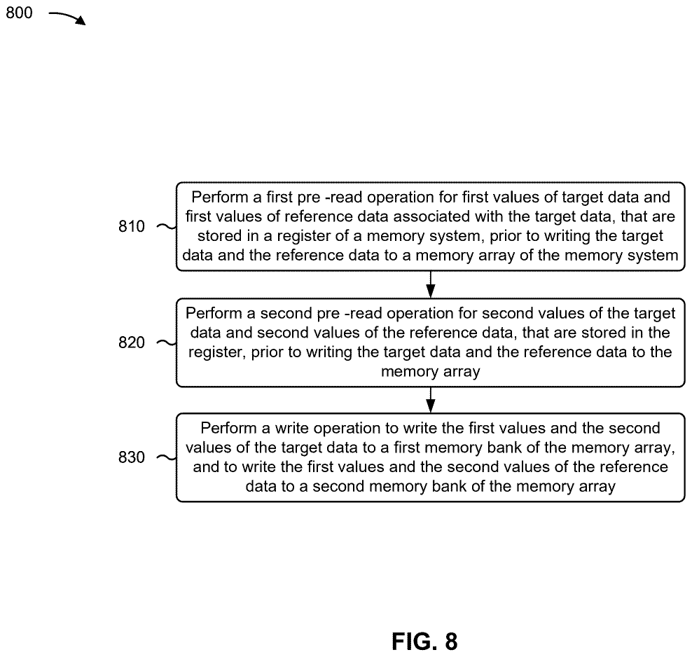

FIG. 8 is a flowchart of an example process 800 associated with writing data to a memory array in a differential memory system described herein. One or more process blocks of FIG. 8 are performed by a differential memory system (e.g., the memory system 100) and/or by another device or a group of devices separate from or including the memory system 100, such as the electronic device 500. Additionally, or alternatively, one or more process blocks of FIG. 8 may be performed by one or more components of the electronic device 500, such as the processor 520, the input component 530, the output component 540, and/or communication component 550.

As shown in FIG. 8, process 800 includes performing a first pre-read operation for first values of target data and first values of reference data associated with the target data, that are stored in a register of a memory system, prior to writing the target data and the reference data to a memory array of the memory system (block 810). For example, the memory system 100 (or the memory controller 106 of the memory system 100) may perform a first pre-read operation for first values of target data and first values of reference data associated with the target data, that are stored in a register (e.g., a register 122) of the memory system, prior to writing the target data and the reference data to a memory array (e.g., a memory array 102) of the memory system, as described herein.

As further shown in FIG. 8, process 800 includes performing a second pre-read operation for second values of the target data and second values of the reference data, that are stored in the register, prior to writing the target data and the reference data to the memory array (block 820). For example, the memory system 100 (or the memory controller 106 of the memory system 100) may perform a second pre-read operation for second values of the target data and second values of the reference data, that are stored in the register, prior to writing the target data and the reference data to the memory array, as described herein.

As further shown in FIG. 8, process 800 includes performing a write operation to write the first values and the second values of the target data to a first memory bank of the memory array, and to write the first values and the second values of the reference data to a second memory bank of the memory array (block 830). For example, the memory system 100 (or the memory controller 106 of the memory system 100) may perform a write operation to write the first values and the second values of the target data to a first memory bank (e.g., a first memory bank 104a) of the memory array, and to write the first values and the second values of the reference data to a second memory bank (e.g., a second memory bank 104b) of the memory array, as described herein.

Process 800 may include additional aspects, such as any single aspect or any combination of aspects described below and/or in connection with one or more other processes described elsewhere herein.

In a first implementation, performing a write operation includes performing a write operation prior to verifying the first values and the second values of the target data in the first memory bank, and prior to verifying the first values and the second values of the reference data in the second memory bank.

In a second implementation, alone or in combination with the first implementation, process 800 includes verifying, after performing the write operation, the first values of the target data written to the first memory bank and the first values of the reference data written to the second memory bank, and verifying, after performing the write operation, the second values of the target data written to the first memory bank and the second values of the reference data written to the second memory bank.

In a third implementation, alone or in combination with one or more of the first and second implementations, verifying the first values of the target data written to the first memory bank and the first values of the reference data written to the second memory bank includes verifying the first values of the target data written to the first memory bank and the first values of the reference data written to the second memory bank prior to verifying the second values of the target data written to the first memory bank and the second values of the reference data written to the second memory bank.

In a fourth implementation, alone or in combination with one or more of the first through third implementations, verifying the first values of the target data written to the first memory bank and the first values of the reference data written to the second memory bank includes verifying the first values of the target data written to the first memory bank and the first values of the reference data written to the second memory bank after verifying the second values of the target data written to the first memory bank and the second values of the reference data written to the second memory bank.

Although FIG. 8 shows example blocks of process 800, in some implementations, process 800 includes additional blocks, fewer blocks, different blocks, or differently arranged blocks than those depicted in FIG. 8. Additionally, or alternatively, two or more of the blocks of process 800 may be performed in parallel.

In this way, binary values of target data and of complementary data are written into a memory array in a highly parallelized and streamlined manner, as opposed to a sequential manner, in order to increase write efficiency and to reduce write and read times in a differential memory system. As described herein, 1-values of target data and of complementary data may be simultaneously pre-read, and 0-values of target data and of complementary data may also be simultaneously pre-read. The 1-values and the 0-values of the target data and of the complementary data may all be pre-read before writing of the target data and the complementary data is performed. The 1-values and the 0-values of the target data may then be written to a first memory bank of the memory array and verified, and the 1-values and the 0-values of the complementary data may then be written to a second memory bank of the memory array and verified. In some implementations, the 1-values and the 0-values of the target data and of the complementary data are all written to the memory array in the same write operation.

As described in greater detail above, some implementations described herein provide a method. The method includes performing, for first values of target data and first values of complementary data associated with the target data that are stored in a plurality of registers of a memory system, a first pre-read operation prior to writing the target data and the complementary data to a memory array of the memory system. The method includes performing, for second values of the target data and second values of the complementary data, a second pre-read operation prior to writing the target data and the complementary data to the memory array. The method includes writing, to a first memory bank of the memory array, the first values of the target data and the second values of the target data. The method includes writing, to a second memory bank of the memory array, the first values of the complementary data and the second values of the complementary data.

As described in greater detail above, some implementations described herein provide a memory system. The memory system includes a memory array that includes a first memory bank and a second memory bank. The memory system includes a plurality of registers. The memory system includes a memory controller. The memory controller is configured to perform a first pre-read operation for first values of target data and first values of complementary data associated with the target data that are stored in the plurality of registers. The memory controller is configured to perform a second pre-read operation for second values of the target data and second values of the complementary data stored in the plurality of registers. The memory controller is configured to write, to the first memory bank, the first values of the target data and the second values of the target data. The memory controller is configured to write, to a second memory bank of the memory array, the first values of the complementary data and the second values of the complementary data. The memory controller is configured to verify the first values of the target data and the second values of the target data that were written to the first memory bank. The memory controller is configured to verify the first values of the complementary data and the second values of the complementary data that were written to the second memory bank.

As described in greater detail above, some implementations described herein provide a method. The method includes performing a first pre-read operation for first values of target data and first values of reference data associated with the target data, that are stored in a register of a memory system, prior to writing the target data and the reference data to a memory array of the memory system. The method includes performing a second pre-read operation for second values of the target data and second values of the reference data, that are stored in the register, prior to writing the target data and the reference data to the memory array. The method includes performing a write operation to write the first values and the second values of the target data to a first memory bank of the memory array, and to write the first values and the second values of the reference data to a second memory bank of the memory array.

As used herein, “satisfying a threshold” may, depending on the context, refer to a value being greater than the threshold, greater than or equal to the threshold, less than the threshold, less than or equal to the threshold, equal to the threshold, not equal to the threshold, or the like.

When “a processor” or “one or more processors” (or another device or component, such as “a controller” or “one or more controllers”) is described or claimed (within a single claim or across multiple claims) as performing multiple operations or being configured to perform multiple operations, this language is intended to broadly cover a variety of processor architectures and environments. For example, unless explicitly claimed otherwise (e.g., via the use of “first processor” and “second processor” or other language that differentiates processors in the claims), this language is intended to cover a single processor performing or being configured to perform all of the operations, a group of processors collectively performing or being configured to perform all of the operations, a first processor performing or being configured to perform a first operation and a second processor performing or being configured to perform a second operation, or any combination of processors performing or being configured to perform the operations. For example, when a claim has the form “one or more processors configured to: perform X; perform Y; and perform Z,” that claim should be interpreted to mean “one or more processors configured to perform X; one or more (possibly different) processors configured to perform Y; and one or more (also possibly different) processors configured to perform Z.”

The foregoing outlines features of several embodiments so that those skilled in the art may better understand the aspects of the present disclosure. Those skilled in the art should appreciate that they may readily use the present disclosure as a basis for designing or modifying other processes and structures for carrying out the same purposes and/or achieving the same advantages of the embodiments introduced herein. Those skilled in the art should also realize that such equivalent constructions do not depart from the spirit and scope of the present disclosure, and that they may make various changes, substitutions, and alterations herein without departing from the spirit and scope of the present disclosure.

What is claimed is:

1. A method, comprising:
performing, for first values of target data and first values of complementary data associated with the target data that are stored in a plurality of registers of a memory system, a first pre-read operation prior to writing the target data and the complementary data to a memory array of the memory system;
performing, for second values of the target data and second values of the complementary data, a second pre-read operation prior to writing the target data and the complementary data to the memory array;
writing, to a first memory bank of the memory array, the first values of the target data and the second values of the target data; and
writing, to a second memory bank of the memory array, the first values of the complementary data and the second values of the complementary data.

2. The method of claim 1, wherein the first values of the target data and the first values of the complementary data comprise 1-values; and
wherein the second values of the target data and the second values of the complementary data comprise 0-values.

3. The method of claim 2, wherein performing the first pre-read operation comprises:
performing the first pre-read operation prior to performing the second pre-read operation.

4. The method of claim 2, wherein performing the first pre-read operation comprises:
performing the second pre-read operation prior to performing the first pre-read operation.

5. The method of claim 1, further comprising:
storing the target data in a first register of the plurality of registers.

6. The method of claim 5, further comprising:
storing the complementary data in a second register of the plurality of registers.

7. The method of claim 1, wherein writing the first values of the target data and the second values of the target data comprises:
writing the first values of the target data and the second values of the target data prior to writing the first values of the complementary data and the second values of the complementary data.

8. The method of claim 1, wherein writing the first values of the target data and the second values of the target data comprises:
writing the first values of the target data and the second values of the target data after writing the first values of the complementary data and the second values of the complementary data.

9. A memory system, comprising:
a memory array, comprising:
a first memory bank; and
a second memory bank;
a plurality of registers; and
a memory controller, configured to:
perform a first pre-read operation for first values of target data and first values of complementary data associated with the target data that are stored in the plurality of registers;
perform a second pre-read operation for second values of the target data and second values of the complementary data stored in the plurality of registers;
write, to the first memory bank, the first values of the target data and the second values of the target data;
write, to a second memory bank of the memory array, the first values of the complementary data and the second values of the complementary data;
verify the first values of the target data and the second values of the target data that were written to the first memory bank; and
verify the first values of the complementary data and the second values of the complementary data that were written to the second memory bank.

10. The memory system of claim 9, wherein the memory controller, to verify the first values of the target data and the second values of the target data that were written to the first memory bank, is configured to:
verify the first values of the target data prior to verifying the second values of the target data.

11. The memory system of claim 9, wherein the memory controller, to verify the first values of the target data and the second values of the target data that were written to the first memory bank, is configured to:
verify the first values of the target after verifying the second values of the target data.

12. The memory system of claim 9, wherein the memory controller, to verify the first values of the complementary data and the second values of the complementary data that were written to the second memory bank, is configured to:
verify the first values of the complementary data prior to verifying the second values of the complementary data.

13. The memory system of claim 9, wherein the memory controller, to verify the first values of the complementary data and the second values of the complementary data that were written to the second memory bank, is configured to:
verify the first values of the complementary data after verifying the second values of the complementary data.

14. The memory system of claim 9, wherein the memory controller, to verify the first values of the target data and the second values of the target data that were written to the first memory bank and to verify the first values of the complementary data and the second values of the complementary data that were written to the second memory bank, is configured to:
verify the first values of the target data that were written to the first memory bank and verify the first values of the complementary data that were written to the second memory bank prior to verifying the second values of the target data that were written to the first memory bank and prior to verifying the second values of the complementary data that were written to the second memory bank.

15. The memory system of claim 9, wherein the memory controller, to verify the first values of the target data and the second values of the target data that were written to the first memory bank and to verify the first values of the complementary data and the second values of the complementary data that were written to the second memory bank, is configured to:
verify the first values of the target data that were written to the first memory bank and verify the first values of the complementary data that were written to the second memory bank after verifying the second values of the target data that were written to the first memory bank and after verifying the second values of the complementary data that were written to the second memory bank.

16. A method, comprising:
performing a first pre-read operation for first values of target data and first values of reference data associated with the target data, that are stored in a register of a memory system, prior to writing the target data and the reference data to a memory array of the memory system;
performing a second pre-read operation for second values of the target data and second values of the reference data, that are stored in the register, prior to writing the target data and the reference data to the memory array; and
performing a write operation to write the first values and the second values of the target data to a first memory bank of the memory array, and to write the first values and the second values of the reference data to a second memory bank of the memory array.

17. The method of claim 16, wherein performing athe write operation comprises:
performing the write operation prior to verifying the first values and the second values of the target data in the first memory bank, and prior to verifying the first values and the second values of the reference data in the second memory bank.

18. The method of claim 16, further comprising:
verifying, after performing the write operation, the first values of the target data written to the first memory bank and the first values of the reference data written to the second memory bank; and
verifying, after performing the write operation, the second values of the target data written to the first memory bank and the second values of the reference data written to the second memory bank.

19. The method of claim 18, wherein verifying the first values of the target data written to the first memory bank and the first values of the reference data written to the second memory bank comprises:
verifying the first values of the target data written to the first memory bank and the first values of the reference data written to the second memory bank prior to verifying the second values of the target data written to the first memory bank and the second values of the reference data written to the second memory bank.

20. The method of claim 18, wherein verifying the first values of the target data written to the first memory bank and the first values of the reference data written to the second memory bank comprises:
verifying the first values of the target data written to the first memory bank and the first values of the reference data written to the second memory bank after verifying the second values of the target data written to the first memory bank and the second values of the reference data written to the second memory bank.
